(19) United States
(12) Patent Application Publication
(10) Pub. No.: US 2025/0294964 A1
(43) Pub. Date: Sep. 18, 2025

(54) DISPLAY DEVICE

(71) Applicant: Sharp Display Technology Corporation, Kameyama City, Mie (JP)

(72) Inventors: Tohru OKABE, Kameyama City, Mie (JP); Shoji OKAZAKI, Kameyama City, Mie (JP); Shinsuke SAIDA, Kameyama City, Mie (JP); Shinji ICHIKAWA, Kameyama City, Mie (JP); Hiroki TANIYAMA, Kameyama City, Mie (JP); Eiji FUJIMOTO, Kameyama City, Mie (JP)

(21) Appl. No.: 18/702,617

(22) PCT Filed: Dec. 27, 2021
(86) PCT No.: PCT/JP2021/048483

§ 371 Date: Apr. 18, 2024

(51) Int. Cl. H10K 59/121; H10D 86/40; H10D 86/60; H10K 59/80

(52) U.S. Cl. CPC H10K 59/1213; H10D 86/423; H10D 86/60; H10K 59/871

(57) ABSTRACT

A display device includes the following: a base substrate; a TFT layer provided on the base substrate; a light-emitting element layer provided on the TFT layer, the TFT layer including a first TFT provided for each subpixel, the first TFT having a first semiconductor layer composed of an oxide semiconductor; and a flattening film provided on the first TFT all over a display region. In at least a location overlapping the first TFT, the flattening film has a low-transmittance portion having a light transmittance of 80% or less at 450 nm.

### TECHNICAL FIELD

The disclosure relates to a display device.

### BACKGROUND ART

Attention has been recently drawn to self-emission organic EL display devices incorporating organic electroluminescence (hereinafter, also referred to as EL) elements, as display devices alternative to liquid crystal displays. Such an organic EL display device has a plurality of thin-film transistors (hereinafter, also referred to as “TFTs”) provided for each subpixel, which is the minimum unit of an image. Here, well-known examples of a semiconductor layer constituting TFTs include, but not limited to, a semiconductor layer made of high-mobility polysilicon, and a semiconductor layer made of an oxide semiconductor having a small leakage current, such as an In—Ga—Zn—O semiconductor.

For instance, Patent Literature 1 discloses an organic EL display device by way of example, as a display device incorporating a TFT substrate provided with TFTs having an oxide semiconductor layer.

### CITATION LIST

### Patent Literature

Patent Literature 1: Japanese Patent No. 6311900

### SUMMARY

### Technical Problem

By the way, in a TFT having a semiconductor layer made of an oxide semiconductor, a threshold value or an S value (a rise coefficient in a sub-threshold region), for instance, may shift due to radiation of light having a short wavelength of 500 nm or less for example, thus possibly deteriorating the TFT's properties. Here, an organic EL display device is structured such that not only external light, but also light emitted by the organic EL element itself easily enters the TFT, thus possibly deteriorating the TFT's properties prominently. Furthermore, a current-driven organic EL display device is structured such that a change in the TFT's properties easily affects image display; hence, a deterioration in the TFT's properties causes, but not limited to, image sticking and other phenomena, degrading display quality.

The disclosure has been made in view of these problems and aims to prevent light-irradiation-caused deterioration in the properties of a TFT including a semiconductor layer made of an oxide semiconductor.

### Solution to Problem

To achieve the above aim, a display device according to the disclosure includes the following: a base substrate; a thin-film transistor layer provided on the base substrate; a light-emitting element layer provided on the thin-film transistor layer, with a plurality of first electrodes, an edge cover that is common, a plurality of light-emitting functional layers, and a second electrode that is common being stacked sequentially in correspondence with a plurality of subpixels constituting a display region, the thin-film transistor layer including a first thin-film transistor provided for each of the plurality of subpixels, the first thin-film transistor having a first semiconductor layer composed of an oxide semiconductor; and a flattening film provided on the first thin-film transistor all over the display region. In at least a location overlapping the first thin-film transistor, the flattening film has a low-transmittance portion having a light transmittance of 80% or less at 450 nm.

### Advantageous Effect of Disclosure

The disclosure can prevent light-irradiation-caused deterioration in the properties of a TFT including a semiconductor layer made of an oxide semiconductor.

### BRIEF DESCRIPTION OF DRAWINGS

FIG. 1 is a plan view of a schematic configuration of an organic EL display device according to a first embodiment of the disclosure.

FIG. 2 is a plan view of a display region of the organic EL display device according to the first embodiment of the disclosure.

FIG. 3 is a sectional view of the display region of the organic EL display device according to the first embodiment of the disclosure.

FIG. 4 is an equivalent circuit diagram illustrating a pixel circuit of the organic EL display device according to the first embodiment of the disclosure.

FIG. 5 is a sectional view of an organic EL layer constituting the organic EL display device according to the first embodiment of the disclosure.

FIG. 6 is a graph showing the light transmittance of a resin film that is to be a flattening film constituting the organic EL display device according to the first embodiment of the disclosure.

FIG. 7 is a sectional view of the display region in a first modification of the organic EL display device according to the first embodiment of the disclosure and corresponds to FIG. 3.

FIG. 8 is a sectional view of the display region in a second modification of the organic EL display device according to the first embodiment of the disclosure and corresponds to FIG. 3.

FIG. 9 is a sectional view of the display region in a third modification of the organic EL display device according to the first embodiment of the disclosure and corresponds to FIG. 3.

FIG. 10 is a sectional view of a display region of an organic EL display device according to a second embodiment of the disclosure and corresponds to FIG. 3.

FIG. 11 is a sectional view of the display region in a modification of the organic EL display device according to the second embodiment of the disclosure.

### DESCRIPTION OF EMBODIMENTS

The embodiments of the disclosure will be detailed on the basis of the drawings. It is noted that the disclosure is not limited to the following embodiments.

### First Embodiment

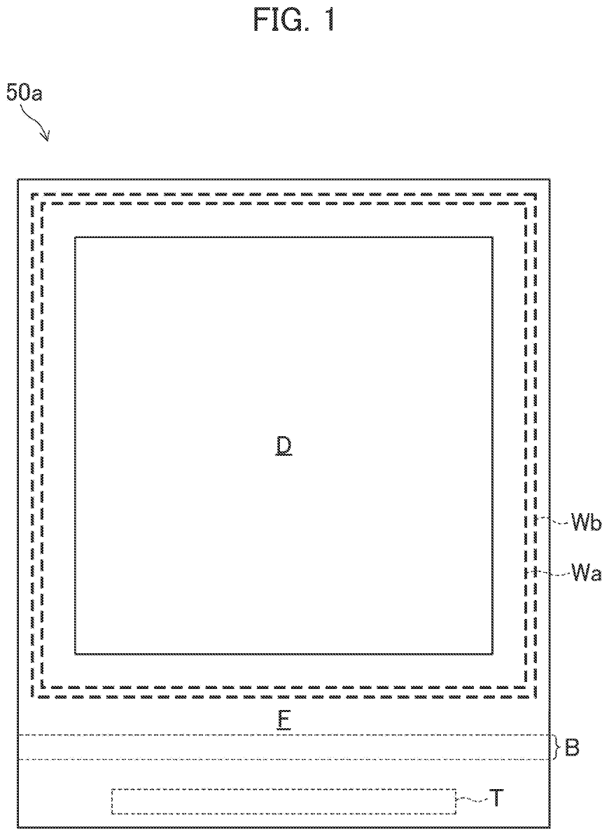

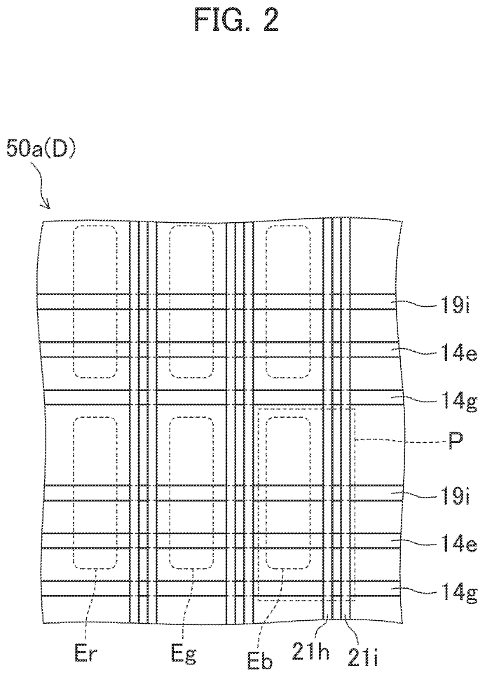

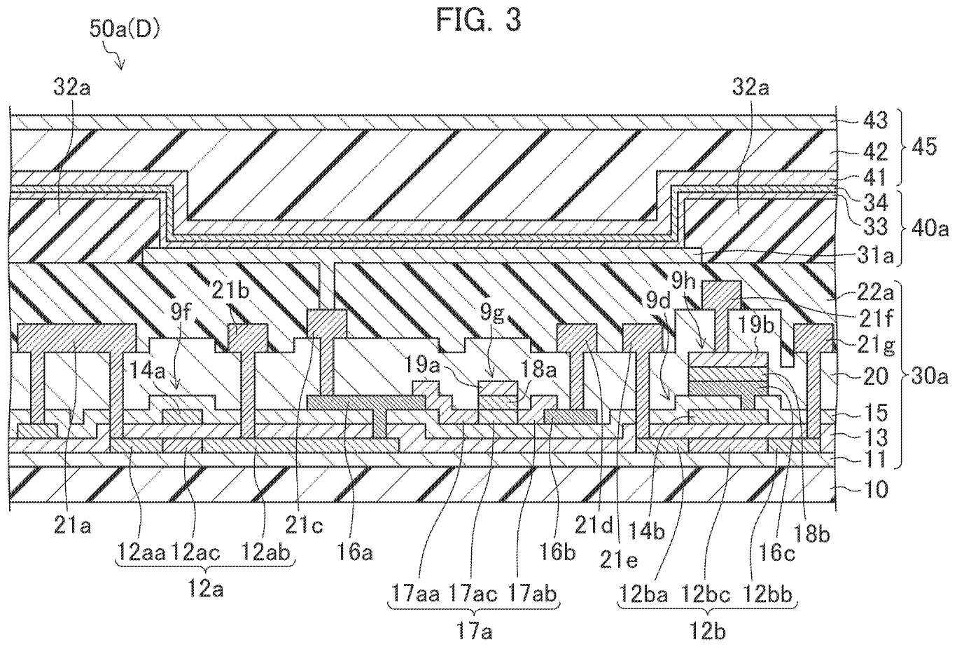

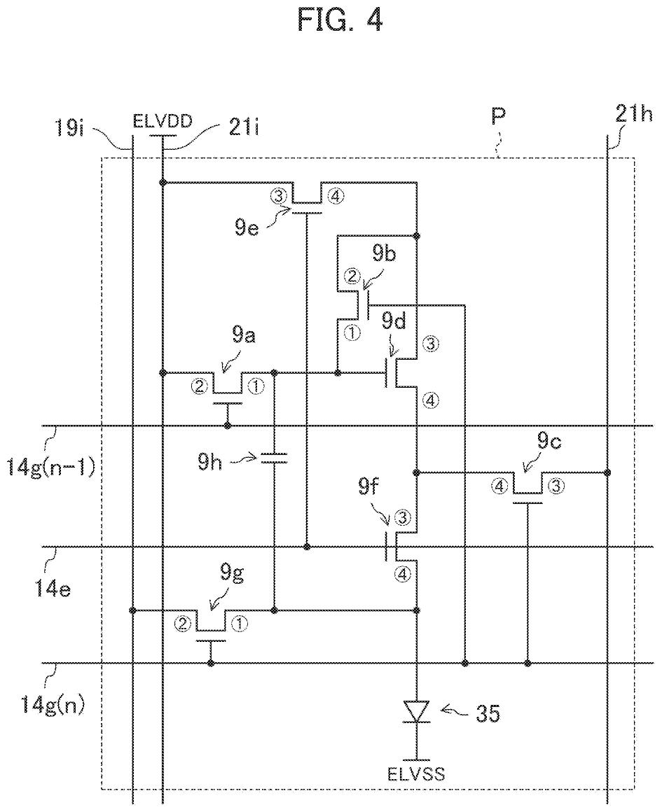

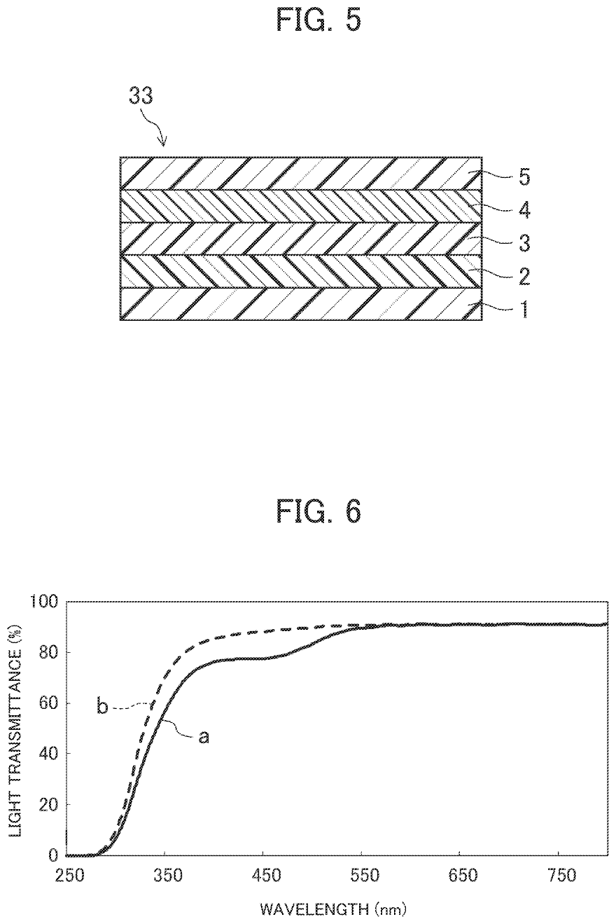

FIG. 1 to FIG. 9 illustrate a display device according to a first embodiment of the disclosure. It is noted that the following embodiments will describe an organic EL display device including an organic EL element layer by way of example, as a display device including a light-emitting element layer. Here, FIG. 1 is a plan view of a schematic configuration of an organic EL display device 50a according to this embodiment. In addition, FIG. 2 and FIG. 3 are a plan view and a sectional view of a display region D of the organic EL display device 50a. In addition, FIG. 4 is an equivalent circuit diagram illustrating a pixel circuit of the organic EL display device 50a. In addition, FIG. 5 is a sectional view of an organic EL layer 33, which constitutes the organic EL display device 50a.

As illustrated in FIG. 1, the organic EL display device 50a has, for instance, the display region D provided rectangularly and configured to perform image display, and a frame region F provided in the form of a frame around the display region D. It is noted that although this embodiment describes the rectangular display region D by way of example, this rectangular shape includes substantially rectangular shapes, such as a shape with an arc-shaped side, a shape with an arc-shaped corner, and a shape with part of a side being cut.

The display region D includes a plurality of subpixels P arranged in matrix, as illustrated in FIG. 2. Further, for instance, a subpixel P having a red light-emitting region Er for red display, a subpixel P having a green light-emitting region Eg for green display, and a subpixel P having a blue light-emitting region Eb for blue display are provided in the display region D so as to be adjacent to one another, as illustrated in FIG. 2. It is noted that the display region D is structured for instance such that three adjacent subpixels P having the red light-emitting region Er, green light-emitting region Eg, and blue light-emitting region Eb constitute a single pixel.

The frame region F includes a terminal section T provided at the lower end in FIG. 1 so as to extend in one direction (the lateral direction in the drawing). The frame region F also includes, as illustrated in FIG. 1, a bending section B provided between the display region D and the terminal section T so as to extend in one direction (the lateral direction of the drawing); here, the bending section B is, for instance, 180° (U-shape) bendable about a bending axis, which is in the lateral direction of the drawing.

The organic EL display device 50a also includes the following as illustrated in FIG. 3: a resin substrate layer 10 provided as a base substrate; a TFT layer 30a provided on the resin substrate layer 10; an organic EL element layer 40a provided as a light-emitting element layer on the TFT layer 30a; and a sealing film 45 provided so as to cover the organic EL element layer 40a.

The resin substrate layer 10 is made of, but not limited to, polyimide resin for instance.

The TFT layer 30a includes the following as illustrated in FIG. 3: a base coat film 11 provided on the resin substrate layer 10; an initialization TFT 9a (see FIG. 4), a compensation TFT 9b (see FIG. 4), a write TFT 9c (see FIG. 4), a driving TFT 9d, a power supply TFT 9e (see FIG. 4), an emission control TFT 9f, an anode discharge TFT 9g, and a capacitor 9h all provided over the base coat film 11 and provided for each subpixel P; and a flattening film 22a provided over the TFTs 9a to 9g and capacitors 9h. Here, the TFT layer 30a includes, as illustrated in FIG. 2, a plurality of gate lines 14g provided so as to extend in parallel with each other in the lateral direction of the drawing. The TFT layer 30a also includes, as illustrated in FIG. 2, a plurality of emission control lines 14e provided so as to extend in parallel with each other in the lateral direction of the drawing. The TFT layer 30a also includes, as illustrated in FIG. 2, a plurality of second initialization power-supply lines 19i provided so as to extend in parallel with each other in the lateral direction of the drawing. It is noted that each emission control line 14e is provided so as to be adjacent to a corresponding one of the gate lines 14g and a corresponding one of the second initialization power-supply lines 19i, as illustrated in FIG. 2. The TFT layer 30a also includes, as illustrated in FIG. 2, a plurality of source lines 21h provided so as to extend in parallel with each other in the longitudinal direction of the drawing. The TFT layer 30a also includes, as illustrated in FIG. 2, a plurality of power supply lines 21i provided so as to extend in parallel with each other in the longitudinal direction of the drawing. It is noted that each power supply line 21i is provided so as to be adjacent to a corresponding one of the source lines 21h, as illustrated in FIG. 2.

The initialization TFT 9a, the compensation TFT 9b, and the anode discharge TFT 9g are provided as first TFTs each having a first semiconductor layer composed of an oxide semiconductor, such as an In—Ga—Zn—O oxide semiconductor, and are each provided with a first gate electrode, a first terminal electrode, and a second terminal electrode. Further, the write TFT 9c, the driving TFT 9d, the power supply TFT 9e, and the emission control TFT 9f are provided as second TFTs each having a second semiconductor layer composed of polysilicon, such as low-temperature polysilicon (LTPS), and are each provided with a second gate electrode, a third terminal electrode, and a fourth terminal electrode. Here, an In—Ga—Zn—O oxide semiconductor is a ternary oxide of indium (In), gallium (Ga), and zinc (Zn) and may contain In, Ga, and Zn at any ratio (composition ratio). Further, this In—Ga—Zn—O semiconductor may be amorphous or crystalline. It is noted that a preferable crystalline In—Ga—Zn—O semiconductor is a crystalline In—Ga—Zn—O semiconductor whose c-axis is nearly perpendicular to a layer surface. It is also noted that other kinds of oxide semiconductor may be included instead of an In—Ga—Zn—O semiconductor. The other kinds of oxide semiconductor may include an In—Sn—Zn—O semiconductor (e.g., In₂O₃—SnO₂—ZnO, InSnZnO) for instance. Here, an In—Sn—Zn—O semiconductor is a ternary oxide of indium (In), tin (Sn), and zinc (Zn). Further, the other kinds of oxide semiconductor may include, but not limited to, an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, cadmium oxide (CdO), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, an In—Ga—Zn—Sn—O semiconductor, InGaO₃(ZnO)₅, magnesium zinc oxide (MgₓZn₁₋ₓO), and cadmium zinc oxide (CdₓZn₁₋ₓO). It is noted that a usable Zn—O semiconductor is an amorphous semiconductor of ZnO with one or more kinds of impurity elements selected from among, but not limited to, a Group I element, a Group XIII element, a Group XIV element, a Group XV element, and a Group XVII element being added thereto, a polycrystalline semiconductor of such ZnO, or a crystallite semiconductor of such ZnO containing amorphous and polycrystalline substances; alternatively, a usable Zn—O semiconductor is a ZnO semiconductor without any impurity elements being added thereto.

As illustrated in FIG. 4, the initialization TFT 9a is configured in each subpixel P such that its first gate electrode is electrically connected to the gate line 14g(n-1) at the anterior stage (n-1 stage), such that its first terminal electrode is electrically connected to a lower conductive layer 16c of the capacitor 9h, which will be described later on, and to the second gate electrode of the driving TFT 9d, and such that its second terminal electrode is electrically connected to the power supply line 21i. It is noted that in the equivalent circuit diagram in FIG. 4, the first terminal electrodes and second terminal electrodes of the first TFTs (the initialization TFT 9a, the compensation TFT 9b, and the anode discharge TFT 9g) are denoted by circled numerals 1 and 2, and the third terminal electrodes and fourth terminal electrodes of the second TFTs (the write TFT 9c, the driving TFT 9d, the power supply TFT 9e and the emission control TFT 9f) are denoted by circled numerals 3 and 4. It is also noted that the equivalent circuit diagram in FIG. 4 includes a part of the pixel circuit of the subpixel P in the (n-1)th row and mth column, as well as the pixel circuit of the subpixel P in the nth row and mth column. It is also noted that although the power supply line 21i for supplying a high power-supply voltage ELVDD serves also as a first initialization power-supply line in the equivalent circuit diagram in FIG. 4, the power supply line 21i and the first initialization power-supply line may be provided separately. It is also noted that although the second initialization power-supply lines 19i receive the same voltage as a low power-supply voltage ELVSS, they may receive a voltage that is different from the low power-supply voltage ELVSS, and that turns off organic EL elements 35.

As illustrated in FIG. 4, the compensation TFT 9b is configured in each subpixel P such that its first gate electrode is electrically connected to the gate line 14g(n) at the target stage (nth stage), such that its first terminal electrode is electrically connected to the second gate electrode of the driving TFT 9d, and such that its second terminal electrode is electrically connected to the third terminal electrode of the drive TFT 9d.

As illustrated in FIG. 4, the write TFT 9c is configured in each subpixel P such that its second gate electrode is electrically connected to the gate line 14g(n) at the target stage (nth stage), such that its third terminal electrode is electrically connected to the corresponding source line 21h, and such that its fourth terminal electrode is electrically connected to the fourth terminal electrode of the driving TFT 9d.

As illustrated in FIG. 4, the driving TFT 9d is configured in each subpixel P such that its second gate electrode 14b (see FIG. 3) is electrically connected to the first terminal electrodes of the respective initialization TFT 9a and compensation TFT 9b, such that its third terminal electrode 21e (see FIG. 3) is electrically connected to the second terminal electrode of the compensation TFT 9b, and the fourth terminal electrode of the power supply TFT 9e, and such that its fourth terminal electrode 21g (see FIG. 3) is electrically connected to the fourth terminal electrode of the write TFT 9c, and the third terminal electrode of the emission control TFT 9f. Here, the driving TFT 9d is configured to control a current that flows through a corresponding one of the organic EL elements 35. Further, the driving TFT 9d includes the following as illustrated in FIG. 3: a second semiconductor layer 12b provided on the base coat film 11; a second gate insulating film 13 provided on the second semiconductor layer 12b; a second gate electrode 14b provided on the second gate insulating film 13 so as to overlap a second channel region 12bc, which will be described later on; a first interlayer insulating film 15 and a second interlayer insulating film 20 sequentially provided so as to cover the second gate electrode 14b; and the third terminal electrode 21e and the fourth terminal electrode 21g provided on the second interlayer insulating film 20 so as to be spaced from each other. Here, the second semiconductor layer 12b has the following as illustrated in FIG. 3: a third conductor region 12ba and a fourth conductor region 12bb provided so as to be spaced from each other; and a second channel region 12bc defined between the third conductor region ba and the fourth conductor region 12bb. Moreover, as illustrated in FIG. 3, the third terminal electrode 21e and the fourth terminal electrode 21g are electrically connected to the third conductor region 12ba and fourth conductor region 12bb of the second semiconductor layer 12b, respectively, via two contact holes formed in a stack of the second gate insulating film 13, first interlayer insulating film 15, and second interlayer insulating film 20.

As illustrated in FIG. 4, the power supply TFT 9e is configured in each subpixel P such that its second gate electrode is electrically connected to the emission control line 14e at the target stage (nth stage), such that its third terminal electrode is electrically connected to the power supply line 21i, and such that its fourth terminal electrode is electrically connected to the third terminal electrode of the driving TFT 9d.

As illustrated in FIG. 4, the emission control TFT 9f is configured in each subpixel P such that its second gate electrode 14a (see FIG. 3) is electrically connected to the emission control line 14e at the target stage (nth stage), such that its third terminal electrode 21a (see FIG. 3) is electrically connected to the fourth terminal electrode of the driving TFT 9d, and such that its fourth terminal electrode 21c (see FIG. 3) is electrically connected to a first electrode 31a of the organic EL element 35, which will be described later on. Further, the emission control TFT 9f includes the following as illustrated in FIG. 3: a second semiconductor layer 12a provided on the base coat film 11; the second gate insulating film 13 provided on the second semiconductor layer 12a; the second gate electrode 14a provided on the second gate insulating film 13 so as to overlap a second channel region 12ac, which will be described later on; the first interlayer insulating film 15 and the second interlayer insulating film 20 sequentially provided so as to cover the second gate electrode 14a; and the third terminal electrode 21a and the fourth terminal electrode 21b (21c) provided on the second interlayer insulating film 20 so as to be spaced from each other. Here, the second semiconductor layer 12a has the following as illustrated in FIG. 3: a third conductor region 12aa and a fourth conductor region 12ab provided so as to be spaced from each other; and a second channel region 12ac defined between the third conductor region 12aa and the fourth conductor region 12ab. Moreover, as illustrated in FIG. 3, the third terminal electrode 21a and the fourth terminal electrode 21b are electrically connected to the third conductor region 12aa and fourth conductor region 12ab of the second semiconductor layer 12a, respectively, via two contact holes formed in a stack of the second gate insulating film 13, first interlayer insulating film 15, and second interlayer insulating film 20. Further, as illustrated in FIG. 3, the fourth terminal electrode 21c is electrically connected to the fourth conductor region 12ab of the second semiconductor layer 12a via a contact hole formed in a stack of the second gate insulating film 13 and first interlayer insulating film 15, via a relay electrode 16a, and via a contact hole formed in the second interlayer insulating film 20.

As illustrated in FIG. 4, the anode discharge TFT 9g is configured in each subpixel P such that its first gate electrode 19a (see FIG. 3) is electrically connected to the gate line 14g(n) at the target stage (nth stage), such that its first terminal electrode 21c (see FIG. 3) is electrically connected to the first electrode 31a of the organic EL element 35, and such that its second terminal electrode 21d (see FIG. 3) is electrically connected to the second initialization power-supply line 19i. It is noted that the first terminal electrode 21c of the anode discharge TFT 9g is shared with the fourth terminal electrode 21c of the emission control TFT 9f. Further, the anode discharge TFT 9g includes the following as illustrated in FIG. 3: a first semiconductor layer 17a provided on the first interlayer insulating film 15; a first gate insulating film 18a provided on the first semiconductor layer 17a; the first gate electrode 19a provided on the first gate insulating film 18a so as to overlap a first channel region 17ac, which will be described later on; the second interlayer insulating film 20 provided so as to cover the first gate electrode 19a; and the first terminal electrode 21c and the second terminal electrode 21d provided on the second interlayer insulating film 20 so as to be spaced from each other. Here, the first semiconductor layer 17a has the following as illustrated in FIG. 3: a first conductor region 17aa and a second conductor region 17ab provided so as to be spaced from each other; and the first channel region 17ac provided between the first conductor region 17aa and the second conductor region 17ab. Moreover, as illustrated in FIG. 3, the first terminal electrode 21c is electrically connected to the first conductor region 17aa of the first semiconductor layer 17a via a contact hole formed in the second interlayer insulating film 20, and via the relay electrode 16a. In addition, as illustrated in FIG. 3, the second terminal electrode 21d is electrically connected to the second conductor region 17ab of the first semiconductor layer 17a via a contact hole formed in the second interlayer insulating film 20, and via a relay electrode 16b.

It is noted that although this embodiment describes, by way of example, a pixel circuit in which the initialization TFT 9a, compensation TFT 9b, and anode discharge TFT 9g are provided as first TFTs each having a first semiconductor layer composed of an oxide semiconductor, and in which the write TFT 9c, driving TFT 9d, power supply TFT 9e, and emission control TFT 9f are provided as second TFTs each having a second semiconductor layer composed of polysilicon, all the TFTs in the pixel circuit, i.e., the initialization TFT 9a, compensation TFT 9b, write TFT 9c, driving TFT 9d, power supply TFT 9e, emission control TFT 9f, and anode discharge TFT 9g may be composed of TFTs having a semiconductor layer composed of an oxide semiconductor.

As illustrated in FIG. 4, the capacitor 9h is configured in each subpixel P such that its lower conductive layer 16c (see FIG. 3) is electrically connected to the second gate electrode 14b of the driving TFT 9d (see FIG. 3), and the first terminal electrodes of the respective initialization TFT 9a and compensation TFT 9b, and such that its upper conductive layer 19b (see FIG. 3) is electrically connected to the first terminal electrode of the anode discharge TFT 9g, the fourth terminal electrode of the emission control TFT 9f, and the first electrode 31a of the organic EL element 35. Further, the capacitor 9h includes the following as illustrated in FIG. 3: the lower conductive layer 16c formed in the same layer using the same material as the relay electrodes 16a and 16b; a first gate insulating film 18b provided on the lower conductive layer 16c; and the upper conductive layer 19b provided on the first gate insulating film 18b and formed in the same layer using the same material as the first gate electrode 19a. It is noted that as illustrated in FIG. 3, the upper conductive layer 19b is electrically connected to a wiring layer 21f, formed in the same layer using the same material as the third terminal electrode 21a and other components, via a contact hole formed in the second interlayer insulating film 20.

The flattening film 22a is provided all over the display region D, has a flat surface in the display region D and is composed of, for instance, an organic resin material, such as acrylic resin, having a thickness of about 1 to 3 μm. In addition, the flattening film 22a entirely has a low-transmittance portion having a light transmittance of 80% or less at 450 nm, and its entire region is a low-transmittance portion.

Here, FIG. 6 is a graph showing measurements of the light transmittance of a resin film that is to be the flattening film 22a (and an edge cover 32a, which will be described later on). Specifically, a first experiment example was applying a 2-μm-thick photosensitive acrylic resin onto a glass substrate, followed by pre-baking at 90° C., followed by ultraviolet irradiation at wavelength 365 nm, followed by post-baking at 220° C., to thus form a first resin film. Further, a second experiment example was similarly applying a 2-μm-thick photosensitive acrylic resin onto a glass substrate, followed by pre-baking at 90° C., followed by post-baking at 220° C. without ultraviolet irradiation, to thus form a second resin film. Then, the first resin film and the second resin film underwent measurement of their light transmittances by the use of an ultraviolet-visible near-infrared spectrophotometer UV-3101 manufactured by SHIMADZU CORPORATION Ltd., and the graph (Curved Line a denotes the second resin film, and Curved Line b denotes the first resin film) shown in FIG. 6 was obtained. The experiment results have revealed that with ultraviolet irradiation between pre-baking and post-baking, the light transmittance at 500 to 550 nm is kept high, whereas without ultraviolet irradiation between pre-baking and post-baking, the light transmittance at 450 nm drops to 80% or less. Accordingly, such a low-transmittance portion as denoted by Curved Line a in the graph of FIG. 6, in which the light transmittance at 450 nm is 80% or less, can be formed by not performing ultraviolet irradiation between pre-baking and post-baking in forming the flattening film 22a. It is noted that a portion having such a light transmittance as denoted by Curved Line b in the graph of FIG. 6 can be formed by selectively performing, in forming the flattening film 22a, ultraviolet irradiation between pre-baking and post-baking to thus make the portion transparent.

As illustrated in FIG. 3, the organic EL element layer 40a includes the following sequentially stacked in correspondence with the plurality of subpixels P: a plurality of first electrodes 31a; an edge cover 32a that is common; a plurality of organic EL layers 33; and a second electrode 34 that is common. Here, the first electrode 31a, organic EL layer 33, and second electrode 34 in each subpixel P constitute the organic EL element 35 (see FIG. 4).

The first electrode 31a is electrically connected to the fourth terminal electrode 21c of the emission control TFT 9f in each subpixel P via a contact hole formed in the flattening film 22a. Further, the first electrodes 31a have the function of injecting holes (positive holes) into the organic EL layers 33. Further, the first electrodes 31a are more desirably formed using a material having a large work function, in order to improve the efficiency of hole injection into the organic EL layers 33. Here, the first electrodes 31a are made of, for instance, a metal material, such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), or tin (Sn). Further, the first electrodes 31a may be made of, but not limited to, alloy of astatine (At) and astatine oxide (AtO₂). Furthermore, the first electrodes 31a may be made of, but not limited to, a conductive oxide, such as tin oxide (SnO), zinc oxide (ZnO), indium tin oxide (ITO), or indium zinc oxide (IZO). Further, the first electrodes 31a may be formed by stacking multiple layers made of the above materials. It is noted that examples of a compound material having a large work function include indium tin oxide (ITO) and indium zinc oxide (IZO).

The edge cover 32a is provided in the form of a lattice shared among all the subpixels P and is composed of, but not limited to, an organic resin material, such as acrylic resin. In addition, the edge cover 23a entirely has a low-transmittance portion having a light transmittance of 80% or less at 450 nm, and its entire region is a low-transmittance portion. It is noted the edge cover 32a can be formed by, like the foregoing flattening film 22a, not performing ultraviolet irradiation between pre-baking and post-baking.

The organic EL layers 33 are provided as light-emitting functional layers, and as illustrated in FIG. 5, each organic EL layer 33 includes a hole injection layer 1, a hole transport layer 2, a light-emitting layer 3, an electron transport layer 4, and an electron injection layer 5 sequentially stacked on the corresponding first electrode 31a.

The hole injection layer 1 is also called an anode buffer layer and has the function of bringing the energy levels of the first electrode 31a and organic EL layer 33 close to each other to improve the efficiency of hole injection from the first electrode 31a into the organic EL layer 33. Here, examples of the material of the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has the function of improving the efficiency of hole transport from the first electrode 31a to the organic EL layer 33. Here, examples of the material of the hole transport layer 2 include a porphyrin derivative, an aromatic tertiary amine compound, a styrylamine derivative, polyvinylcarbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The light-emitting layer 3 is a region where holes and electrons are respectively injected from the first electrode 31a and second electrode 34 applied with voltage, and where the holes and electrons recombine together. Here, the light-emitting layer 3 is made of a material having high efficiency of light emission. Moreover, examples of the material of the light-emitting layer 3 include a metal oxinoid compound [8-hydroxyquinoline metal complex], a naphthalene derivative, an anthracene derivative, a diphenylethylene derivative, a vinyl acetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrilbenzene derivative, a perylene derivative, a perynone derivative, an aminopyrene derivative, a pyridine derivative, a rhodamine derivative, an acridine derivative, phenoxazone, a quinacridone derivative, rubrene, poly-p-phenylenevinylene, and polysilane.

The electron transport layer 4 has the function of moving electrons to the light-emitting layer 3 efficiently. Here, an example of the material of the electron transport layer 4 is organic compounds, including an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has the function of bringing the energy levels of the second electrode 34 and organic EL layer 33 close to each other to improve the efficiency of electron injection from the second electrode 34 into the organic EL layer 33. This function can lower a voltage for driving the organic EL element 35. It is noted that the electron injection layer 5 is also called a cathode buffer layer. Here, examples of the material of the electron injection layer 5 include inorganic alkali compounds, such as lithium fluoride (LiF), magnesium fluoride (MgF₂), calcium fluoride (CaF₂), strontium fluoride (SrF₂), or barium fluoride (BaF₂), as well as aluminum oxide (Al₂O₃) and strontium oxide (SrO).

The second electrode 34 is shared among all the subpixels P so as to cover the individual organic EL layers 33 and the edge cover 32a, as illustrated in FIG. 3. Further, the second electrode 34 has the function of injecting electrons into the organic EL layers 33. Further, the second electrode 34 is more desirably made of a material having a small work function, in order to improve the efficiency of electron injection into the organic EL layers 33. Here, examples of the material of the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be made of, for instance, alloy of magnesium (Mg) and copper (Cu), alloy of magnesium (Mg) and silver (Ag), alloy of sodium (Na) and potassium (K), alloy of astatine (At) and astatine oxide (AtO₂), alloy of lithium (Li) and aluminum (Al), alloy of lithium (Li), calcium (Ca) and aluminum (Al), or alloy of lithium fluoride (LiF), calcium (Ca) and aluminum (Al). Further, the second electrode 34 may be composed of a conductive oxide, such as tin oxide (SnO), zinc oxide (ZnO), indium tin oxide (ITO), or indium zinc oxide (IZO). Further, the second electrode 34 may be formed by stacking multiple layers made of the above materials. It is noted that examples of a material having a small work function include magnesium (Mg), lithium (Li), lithium fluoride (LiF), magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (Al).

As illustrated in FIG. 3, the sealing film 45 is provided so as to cover the second electrode 34 and includes a first inorganic sealing film 41, an organic sealing film 42, and a second inorganic sealing film 43 sequentially stacked on the second electrode 34, and the sealing film 45 has the function of protecting the organic EL layers 33 of the organic EL elements 35 from moisture, oxygen, and other things. Here, the first inorganic sealing film 41 and the second inorganic sealing film 43 are composed of an inorganic insulating film, such as a silicon nitride film, a silicon oxide film, or a silicon oxide nitride film. Further, the organic sealing film 42 is made of an organic resin material, such as acrylic resin, epoxy resin, silicone resin, polyurea resin, parylene resin, polyimide resin, or polyamide resin.

As illustrated in FIG. 1, the organic EL display device 50a also includes, in the frame region F, a first dam wall Wa provided in the form of a frame so as to surround the display region D, and a second dam wall Wb provided in the form of a frame around the first dam wall Wa. Here, the first dam wall Wa and the second dam wall Wb each include, for instance, a lower resin layer formed in the same layer using the same material as the flattening film 22a, and an upper resin layer provided on the lower resin layer, and formed in the same layer using the same material as the edge cover 32a. It is noted that the first wall Wa is provided so as to overlap the outer periphery of the organic sealing film 42 of the sealing film 45 and is configured to prevent the spread of an ink that constitutes the organic sealing film 42.

In each subpixel P of the organic EL display device 50a having the foregoing configuration, the emission control line 14e is firstly selected and deactivated, thus rendering the organic EL element 35 non-luminous. In this non-luminous state, the gate line 14g(n-1) at the anterior stage is selected, and a gate signal is input to the initialization TFT 9a via the gate line 14g(n-1), thus turning on the initialization TFT 9a, thus applying the high power-supply voltage ELVDD of the power supply line 21i to the capacitor 9h, and turning on the driving TFT 9d. Accordingly, the electric charge within the capacitor 9h is discharged to thus initialize the voltage applied to the second gate electrode of the driving TFT 9d. Next, the gate line 14(n) at the target stage is selected and activated, thus turning on the compensation TFT 9b and the write TFT 9c, thus writing a predetermined voltage corresponding to a source signal transmitted via the corresponding source line 21h, into the capacitor 9h via the driving TFT 9d being in diode connection, and turning on the anode discharge TFT 9g, thus applying an initialization signal to the first electrode 31a of the organic EL element 35 via the second initialization power-supply line 19i to thus reset the electric charge accumulated in the first electrode 31a. Then, the emission control line 14e is selected, thus turning on the power supply TFT 9e and the emission control TFT 9f, thus supplying, from the power supply line 21i to the organic EL element 35, a driving current corresponding to the voltage applied to the second gate electrode of the driving TFT 9d. In this way, the organic EL element 35 in each subpixel P emits light at a luminance level corresponding to the driving current, so that the organic EL display device 50a displays an image.

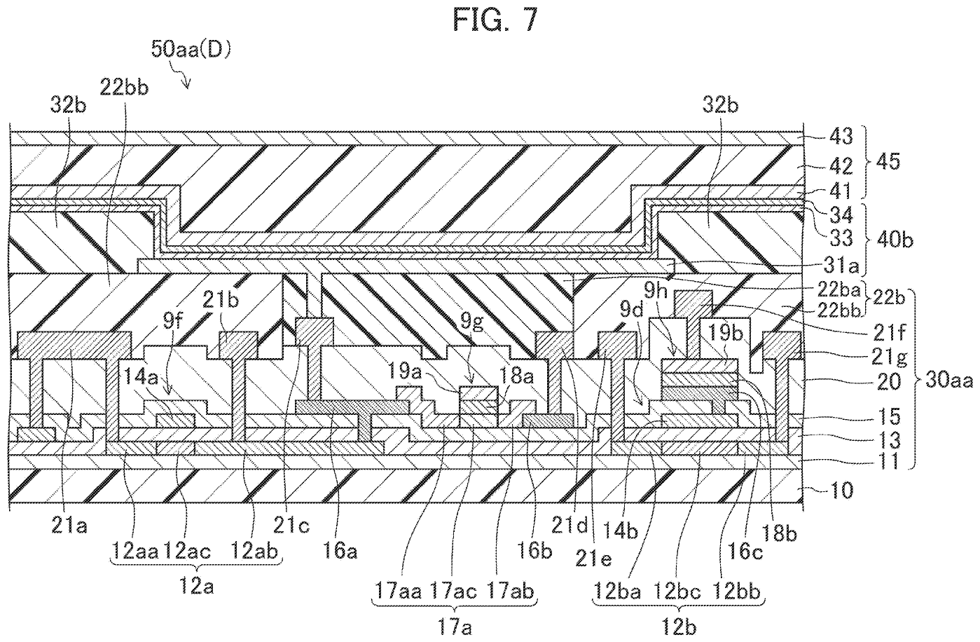

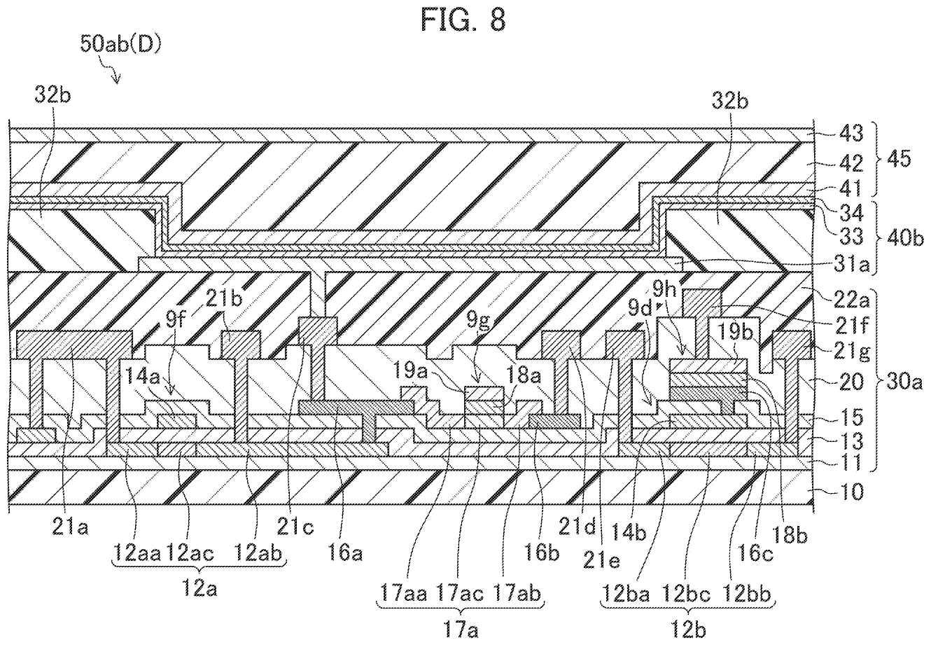

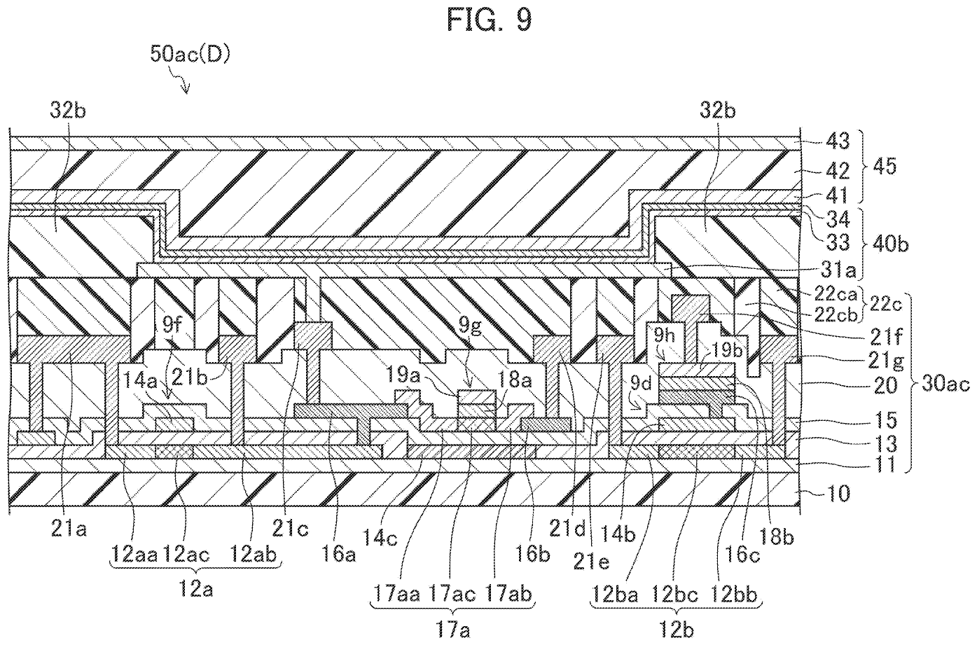

It is noted that this embodiment describes, by way of example, the organic EL display device 50a in which the flattening film 22a and the edge cover 32a are low-transmittance portions in their entire regions; in other embodiments, an organic EL display device 50aa illustrated in FIG. 7, an organic EL display device 50ab illustrated in FIG. 8, and an organic EL display device 50ac illustrated in FIG. 9 may be provided. Here, FIG. 7, FIG. 8, and FIG. 9 are sectional views of the display region D in a first modification (organic EL display device 50aa), a second modification (organic EL display device 50ab), and a third modification (organic EL display device 50ac) of the organic EL display device 50a, and they correspond to FIG. 3.

To be specific, the organic EL display device 50aa includes the following as illustrated in FIG. 7: the resin substrate layer 10; a TFT layer 30aa provided on the resin substrate layer 10; an organic EL element layer 40b provided on the TFT layer 30aa; and the sealing film 45 provided so as to cover the organic EL element layer 40b.

The TFT layer 30aa includes the following as illustrated in FIG. 7: the base coat film 11 provided on the resin substrate layer 10; the initialization TFT 9a (see FIG. 4), the compensation TFT 9b (see FIG. 4), the write TFT 9c (see FIG. 4), the driving TFT 9d, the power supply TFT 9e (see FIG. 4), the emission control TFT 9f, the anode discharge TFT 9g, and the capacitor 9h all provided over the base coat film 11 and provided for each subpixel P; and a flattening film 22b provided over the TFTs 9a to 9g and capacitors 9h. Like the TFT layer 30a according to this embodiment, the TFT layer 30aa also includes a plurality of gate lines 14g, a plurality of emission control lines 14e, a plurality of second initialization power-supply lines 19i, a plurality of source lines 21h, and a plurality of power supply lines 21i. Here, the flattening film 22b is provided all over the display region D, has a flat surface in the display region D and is composed of, for instance, an organic resin material, such as acrylic resin, having a thickness of about 1 to 3 μm. In addition, the flattening film 22b has a low-transmittance portion 22ba having a light transmittance of 80% or less at 450 nm (see Curved Line a in the graph of FIG. 6), and a high-transmittance portion 22bb having, at 550 nm or less, a light transmittance higher than the light transmittance of the low-transmittance portion 22ba (see Curved Line b in the graph of FIG. 6). It is noted that the low-transmittance portion 22ba is provided in a location overlapping the first TFTs, such as the anode discharge TFT 9g, as illustrated in FIG. 7. It is also noted that the low-transmittance portion 22ba can be formed by not performing ultraviolet irradiation via a photomask between pre-baking and post-baking, and that the high-transmittance portion 22bb can be formed by selectively performing ultraviolet irradiation via a photomask between pre-baking and post-baking to thus make the portion transparent.

As illustrated in FIG. 7, the organic EL element layer 40b includes the following sequentially stacked in correspondence with the plurality of subpixels P: a plurality of first electrodes 31a; an edge cover 32b that is common; a plurality of organic EL layers 33; and the second electrode 34 that is common. Here, the edge cover 32b is provided in the form of a lattice shared among all the subpixels P and is composed of, but not limited to, an organic resin material, such as acrylic resin. In addition, the edge cover 32b has a property (see Curved Line b in the graph of FIG. 6) where its light transmittance at 550 nm or less is higher than the light transmittance of the low-transmittance portion 22ba, which constitutes the flattening film 22b. It is noted the edge cover 32b can be formed by performing ultraviolet irradiation between pre-baking and post-baking to thus make this portion transparent.

Further, the organic EL display device 50ab includes the following as illustrated in FIG. 8: the resin substrate layer 10; the TFT layer 30a (of the foregoing organic EL display device 50a) provided on the resin substrate layer 10; the organic EL element layer 40b (of the foregoing organic EL display device 50aa) provided on the TFT layer 30a; and the sealing film 45 provided so as to cover the organic EL element layer 40b.

Further, the organic EL display device 50ac includes the following as illustrated in FIG. 9: the resin substrate layer 10; a TFT layer 30ac provided on the resin substrate layer 10; the organic EL element layer 40b (of the foregoing organic EL display device 50aa) provided on the TFT layer 30ac; and the sealing film 45 provided so as to cover the organic EL element layer 40b.

The TFT layer 30ac includes the following as illustrated in FIG. 9: the base coat film 11 provided on the resin substrate layer 10; the initialization TFT 9a (see FIG. 4), the compensation TFT 9b (see FIG. 4), the write TFT 9c (see FIG. 4), the driving TFT 9d, the power supply TFT 9e (see FIG. 4), the emission control TFT 9f, the anode discharge TFT 9g, and the capacitor 9h all provided over the base coat film 11 and provided for each subpixel P; and a flattening film 22c provided over the TFTs 9a to 9g and capacitors 9h. Like the TFT layer 30a according to this embodiment, the TFT layer 30ac also includes a plurality of gate lines 14g, a plurality of emission control lines 14e, a plurality of second initialization power-supply lines 19i, a plurality of source lines 21h, and a plurality of power supply lines 21i. Here, as illustrated in FIG. 9, the anode discharge TFT 9g is structured such that a third gate electrode 14c is provided on the first semiconductor layer 17a adjacent to the resin substrate layer 10 with the first interlayer insulating film 15 interposed therebetween, so as to overlap the first semiconductor layer 17a. The anode discharge TFT 9g is thus configured to control properties, such as an S value, by the use of the third gate electrode 14c. Further, the flattening film 22c is provided all over the display region D, has a flat surface in the display region D and is composed of, for instance, an organic resin material, such as acrylic resin, having a thickness of about 1 to 3 μm. In addition, the flattening film 22c has a low-transmittance portion 22ca having a light transmittance of 80% or less at 450 nm (see Curved Line a in the graph of FIG. 6), and a high-transmittance portion 22cb having, at 550 nm or less, a light transmittance higher than the light transmittance of the low-transmittance portion 22ca (see Curved Line b in the graph of FIG. 6). It is noted that as illustrated in FIG. 9, the low-transmittance portion 22ca is provided in a location overlapping the second gate electrodes 14a and 14b, third terminal electrodes 21a and 21e, and fourth terminal electrodes 21b and 21g of the second TFTs, in addition to the location overlapping the first TFTs, such as the anode discharge TFT 9g. It is also noted that the low-transmittance portion 22ca can be formed by performing ultraviolet irradiation from the back side (from the resin substrate layer 10) in such a manner that the second gate electrodes 14a and 14b, third terminal electrodes 21a and 21e, and fourth terminal electrodes 21b and 21g of the second TFTs are masked, and by not performing ultraviolet irradiation between pre-baking and post-baking, and that the high-transmittance portion 22cb can be formed by performing ultraviolet irradiation from the back side (from the resin substrate layer 10) similarly, and by selectively performing ultraviolet irradiation between pre-baking and post-baking to thus make the portion transparent.

Next, a method for manufacturing the organic EL display device 50a according to this embodiment will be described. Here, the method for manufacturing the organic EL display device 50a according to this embodiment includes a step of forming a TFT layer, a step of forming an organic EL element layer, and a step of forming a sealing film.

### Step of Forming TFT Layer

The first process step is forming the base coat film 11 by forming a silicon oxide film (about 250 nm thick) and a silicon nitride film (about 100 nm thick) sequentially onto the resin substrate layer 10 formed on, for instance, a glass substrate through, for instance, plasma chemical vapor deposition (CVD).

The next is forming, for instance, an amorphous silicon film (about 50 nm thick) onto the substrate surface with the base coat film 11 formed thereon, through plasma CVD, and crystallizing the amorphous silicon film through laser annealing or other methods to thus form a polysilicon film, followed by patterning the polysilicon film to thus form the second semiconductor layer 12a and other components.

Furthermore, a silicon oxide film (about 100 nm thick) is formed onto the substrate surface with the second semiconductor layer 12a formed thereon, through, for instance, plasma CVD to thus form the second gate insulating film 13, then, a metal film, such as a molybdenum film (about 100 nm thick) is formed through, for instance, sputtering, and then, the metal film undergoes patterning to thus form the second gate electrode 14a and other components.

The next is forming a silicon oxide film (about 100 nm thick) onto the substrate surface with the second gate electrode 14a and other components formed thereon, through, for instance, plasma CVD to thus form the first interlayer insulating film 15, followed by forming a metal film, such as a molybdenum film (about 100 nm thick), through, for instance, sputtering, followed by patterning the metal film to thus form the relay electrode 16a and other components.

The next is forming a semiconductor film (about 30 nm thick), such as a film of InGaZnO₄, onto the substrate surface with the relay electrode 16a and other components formed thereon, through, for instance, sputtering, and annealing the semiconductor film, followed by patterning the semiconductor film to thus form the first semiconductor layer 17a.

Furthermore, a silicon oxide film (about 300 nm thick) is formed onto the substrate surface with the first semiconductor layer 17a formed thereon, through, for instance, plasma CVD, then, a metal film, such as a molybdenum film (about 100 nm thick), is formed through sputtering, and then, the stack of these films undergoes patterning to thus form the first gate insulating film 18a, the first gate electrode 19a and other components.

The next is forming the second interlayer insulating film 20 by forming a silicon oxide film (about 150 nm thick) onto the substrate surface with the first gate insulating film 18a, first gate electrode 19a and other components formed thereon, through, for instance, plasma CVD.

The next is forming contact holes as appropriate in the second gate insulating film 13, first interlayer insulating film 15, and second interlayer insulating film 20, followed by sequentially forming a titanium film (about 50 nm thick), an aluminum film (about 400 nm thick), a titanium film (about 50 nm thick) and other components through, for instance, sputtering to thus form a metal stacked film, followed by patterning the metal stacked film to thus form the third terminal electrode 21a, the fourth terminal electrode 21b and other components.

Furthermore, a photosensitive resin film of acrylic (about 2 μm thick) is applied onto the substrate surface with the third terminal electrode 21a, fourth terminal electrode 21b and other components formed thereon, through, but not limited to, slit coating, and then, this applied film undergoes pre-baking, exposure, development, and post-baking to thus form the flattening film 22a. It is noted that no ultraviolet irradiation for making the film transparent is performed between the development and the post-baking.

The TFT layer 30a can be formed through the foregoing process steps.

### Step of Forming Organic EL Element Layer

The organic EL element layer 40a is formed by forming, through a well-known method, the first electrodes 31a, the edge cover 32a, the organic EL layers 33 (the hole injection layer 1, the hole transport layer 2, the light-emitting layer 3, the electron transport layer 4, and the electron injection layer 5), and the second electrode 34 onto the flattening film 22a of the TFT layer 30a formed in the step of forming the TFT layer. Here, to form the edge cover 32a, a photosensitive resin film of acrylic (about 2 μm thick) is applied onto the substrate surface with the first electrodes 31a formed thereon, through, but not limited to, slit coating, and then, this applied film undergoes pre-baking, exposure, development, and post-baking, without ultraviolet irradiation for making the film transparent between the development and the post-baking.

### Step of Forming Sealing Film

Through a well-known method, the sealing film 45 (the first inorganic sealing film 41, the organic sealing film 42, and the second inorganic sealing film 43) is formed onto the organic EL element layer 40a formed in the step of forming the organic EL element layer. The next is attaching a protective sheet (not shown) onto the substrate surface with the sealing film 45 formed thereon, followed by laser light irradiation from the resin substrate layer 10 adjacent to the glass substrate, to thus detach the glass substrate from the lower surface of the resin substrate layer 10, followed by further attaching a protective sheet (not shown) onto the lower surface of the resin substrate layer 10 with the glass substrate detached therefrom.

The organic EL display device 50a according to this embodiment can be manufactured through the foregoing process steps.

As described above, the organic EL display device 50a according to this embodiment is structured such that the flattening film 22a, provided so as to cover the initialization TFT 9a, compensation TFT 9b, write TFT 9c, driving TFT 9d, power supply TFT 9e, emission control TFT 9f, and anode discharge TFT 9g, is entirely a low-transmittance portion having a light transmittance of 80% or less at 450 nm. This structure can prevent light-irradiation-caused deterioration in the properties of the initialization TFT 9a, compensation TFT 9b, write TFT 9c, driving TFT 9d, power supply TFT 9e, emission control TFT 9f, and anode discharge TFT 9g. The first TFTs, such as the anode discharge TFT 9g, including the first semiconductor layer 17a composed of an oxide semiconductor possibly involve deterioration in their properties due to radiation of light of a short wavelength of 500 nm or less; such light-irradiation-caused deterioration in the TFT's properties can be effectively prevented particularly in the first TFTs. This prevents image sticking and other phenomena during image display, thereby achieving high display quality. Further, a camera, a fingerprint sensor, a face authentication sensor, and other things can function even when they are placed on the back side (a side adjacent to the resin substrate layer 10), because a high light transmittance is achieved in a wavelength region that is used with a sensor for wavelength 550 nm or greater.

In addition, the organic EL display device 50a according to this embodiment, which is structured such that the entire edge cover 32a is, as well, a low-transmittance portion having a light transmittance of 80% or less at 450 nm, can further prevent light-irradiation-caused deterioration in the properties of the initialization TFT 9a, compensation TFT 9b, write TFT 9c, driving TFT 9d, power supply TFT 9e, emission control TFT 9f, and anode discharge TFT 9g.

### Second Embodiment

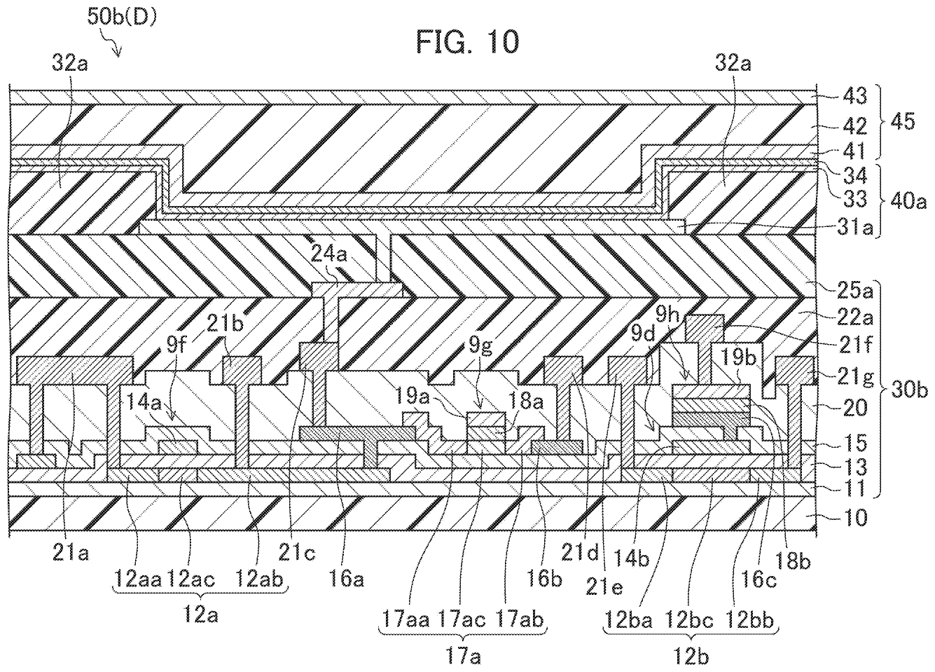

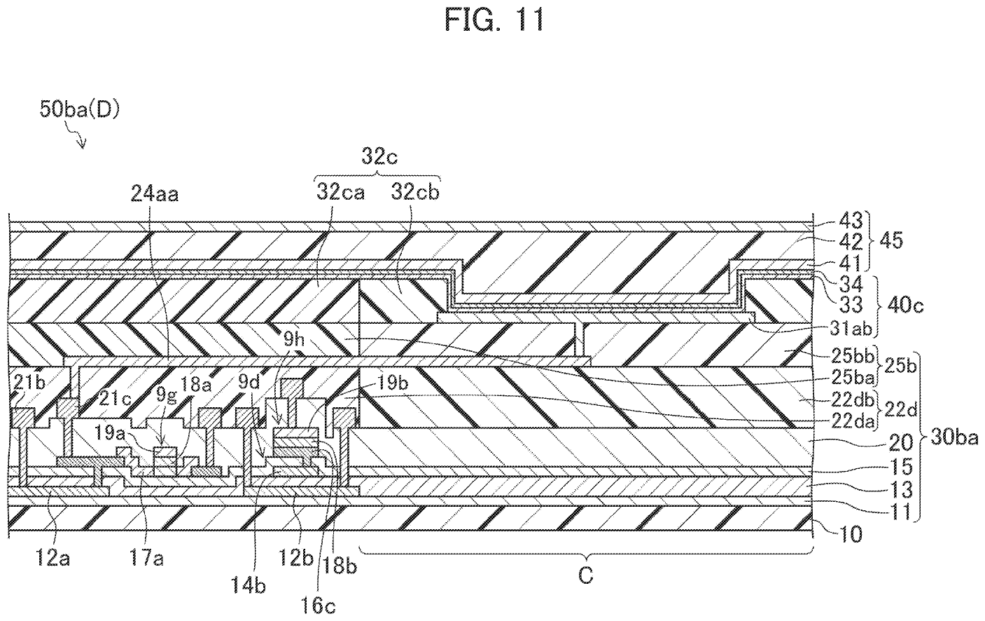

FIG. 10 and FIG. 11 illustrate a display device according to a second embodiment of the disclosure. Here, FIG. 10 is a sectional view of the display region D of an organic EL display device 50b according to this embodiment and corresponds to FIG. 3. In addition, FIG. 11 is a sectional view of the display region D in a modification (organic EL display device 50ba) of the organic EL display device 50b. It is noted that the same components as those illustrated in FIG. 1 to FIG. 9 will be denoted by the same signs in the following embodiment, and their detailed description will be omitted.

The first embodiment has described, by way of example, the organic EL display device 50a having a flattening film of single-layer structure. This embodiment will describe the organic EL display device 50b having a flattening film of dual-layer structure.

Like the organic EL display device 50a according to the first embodiment, the organic EL display device 50b has the display device D, and the frame region F provided in the form of a frame around the display region D.

Like the organic EL display device 50a according to the first embodiment, the organic EL display device 50b also includes the resin substrate layer 10, a TFT layer 30b provided on the resin substrate layer 10, the organic EL element layer 40a provided on the TFT layer 30b, and the sealing film 45 provided so as to cover the organic EL element layer 40a.

The TFT layer 30b includes the following as illustrated in FIG. 10: the base coat film 11 provided on the resin substrate layer 10; the initialization TFT 9a (see FIG. 4), the compensation TFT 9b (see FIG. 4), the write TFT 9c (see FIG. 4), the driving TFT 9d, the power supply TFT 9e (see FIG. 4), the emission control TFT 9f, the anode discharge TFT 9g, and the capacitor 9h all provided over the base coat film 11 and provided for each subpixel P; a first flattening film 22a (substantially the same as the flattening film 22a according to the first embodiment) provided over the TFTs 9a to 9g and capacitors 9h; and a second flattening film 25a provided on the first flattening film 22a. Like the TFT layer 30a according to the first embodiment, the TFT layer 30b also includes a plurality of gate lines 14g, a plurality of emission control lines 14e, a plurality of second initialization power-supply lines 19i, a plurality of source lines 21h, and a plurality of power supply lines 21i. Further, as illustrated in FIG. 10, the TFT layer 30b is structured such that a relay electrode 24a is provided between the first flattening film 22a and the second flattening film 25a, and such that in each subpixel P, the first terminal electrode 21c of the anode discharge TFT 9g and the first electrode 31a of the organic EL element layer 40a are electrically connected together via the relay electrode 24a. Here, the second flattening film 25a is provided all over the display region D, has a flat surface in the display region D and is composed of, for instance, an organic resin material, such as acrylic resin, having a thickness of about 1 to 3 μm. In addition, the second flattening film 25a entirely has a low-transmittance portion having a light transmittance of 80% or less at 450 nm, and its entire region is a low-transmittance portion.

Like the organic EL display device 50a according to the first embodiment, the organic EL display device 50b of the foregoing configuration is configured such that the organic EL element 35 in each subpixel P emits light at a luminance level corresponding to a driving current, so that the organic EL display device 50b displays an image.

It is noted that this embodiment describes, by way of example, the organic EL display device 50b with no imaging region defined within the display region D; in another embodiment, an organic EL display device 50ba illustrated in FIG. 11 may be provided with an imaging region C defined within the display region D.

To be specific, the organic EL display device 50ba has the display region D within which the imaging region C is provided, and the frame region F provided in the form of a frame around the display region D. Here, the imaging region C has a back surface (a surface adjacent to the resin substrate layer 10) on which electronic components, including a camera, a fingerprint sensor, and a face authentication sensor, are to be placed.

The organic EL display device 50ba includes the following as illustrated in FIG. 11: the resin substrate layer 10; a TFT layer 30ba provided on the resin substrate layer 10; an organic EL element layer 40c provided on the TFT layer 30ba; and the sealing film 45 provided so as to cover the organic EL element layer 40c.

The TFT layer 30ba includes the following as illustrated in FIG. 11: the base coat film 11 provided on the resin substrate layer 10; the initialization TFT 9a (see FIG. 4), the compensation TFT 9b (see FIG. 4), the write TFT 9c (see FIG. 4), the driving TFT 9d, the power supply TFT 9e (see FIG. 4), the emission control TFT 9f, the anode discharge TFT 9g, and the capacitor 9h all provided over the base coat film 11 and provided for each subpixel P; a first flattening film 22d provided over the TFTs 9a to 9g and capacitors 9h; and a second flattening film 25b provided on the first flattening film 22d. Like the TFT layer 30a according to the first embodiment, the TFT layer 30ba also includes a plurality of gate lines 14g, a plurality of emission control lines 14e, a plurality of second initialization power-supply lines 19i, a plurality of source lines 21h, and a plurality of power supply lines 21i. Further, the TFT layer 30ba is structured such that the relay electrode 24a and a relay electrode 24aa are provided between the first flattening film 22d and the second flattening film 25b, and such that in each subpixel P, the first terminal electrode 21c of the anode discharge TFT 9g and the first electrode 31a of the organic EL element layer 40c are electrically connected together via the relay electrode 24a. Here, in the subpixel P in the imaging region C, as illustrated in FIG. 11, the relay electrode 24aa, which is an extended part of the relay electrode 24a, is provided, and the first terminal electrode 21c of the anode discharge TFT 9g and a first electrode 31ab of the organic EL element layer 40c are electrically connected together via the relay electrode 24aa. It is noted that in the subpixel P in the imaging region C, the first TFTs corresponding to this subpixel P, such as at least the anode discharge TFT 9g, are provided in the surrounding subpixel P, as illustrated in FIG. 11. Further, the first flattening film 22d is provided all over the display region D, has a flat surface in the display region D and is composed of, for instance, an organic resin material, such as acrylic resin, having a thickness of about 1 to 3 μm. In addition, the first flattening film 22b has a low-transmittance portion 22da having a light transmittance of 80% or less at 450 nm (see Curved Line a in the graph of FIG. 6), and a high-transmittance portion 22db having, at 550 nm or less, a light transmittance higher than the light transmittance of the low-transmittance portion 22da (see Curved Line b in the graph of FIG. 6). It is noted that the low-transmittance portion 22da is provided in a location not overlapping the imaging region C in the display region D, as illustrated in FIG. 11. It is also noted that the low-transmittance portion 22da can be formed by not performing ultraviolet irradiation via a photomask between pre-baking and post-baking, and that the high-transmittance portion 22db can be formed by selectively performing ultraviolet irradiation via a photomask between pre-baking and post-baking to thus make the portion transparent. Furthermore, the second flattening film 25b is provided all over the display region D, has a flat surface in the display region D and is composed of, for instance, an organic resin material, such as acrylic resin, having a thickness of about 1 to 3 μm. In addition, the second flattening film 25b has a low-transmittance portion 25ba having a light transmittance of 80% or less at 450 nm (see Curved Line a in the graph of FIG. 6), and a high-transmittance portion 25bb having, at 550 nm or less, a light transmittance higher than the light transmittance of the low-transmittance portion 25ba (see Curved Line b in the graph of FIG. 6). It is noted that the low-transmittance portion 25ba is provided in a location not overlapping the imaging region C in the display region D, as illustrated in FIG. 11. It is also noted that the low-transmittance portion 25ba can be formed by not performing ultraviolet irradiation via a photomask between pre-baking and post-baking, and that the high-transmittance portion 25bb can be formed by selectively performing ultraviolet irradiation via a photomask between pre-baking and post-baking to thus make the portion transparent.

As illustrated in FIG. 11, the organic EL element layer 40c includes the following stacked sequentially in correspondence with the plurality of subpixels P: a plurality of first electrodes 31a and 31ab; an edge cover 32c that is common; a plurality of organic EL layers 33; and the second electrode 34 that is common. It is noted that the first electrodes 31ab are the first electrodes 31a provided in the imaging region C more sparsely than those in the normal subpixels P in the display region D. Here, the edge cover 32c is provided in the form of a lattice shared among all the subpixels P and is composed of, but not limited to, an organic resin material, such as acrylic resin. In addition, the edge cover 32c has a low-transmittance portion 32ca having a light transmittance of 80% or less at 450 nm (see Curved Line a in the graph of FIG. 6), and a high-transmittance portion 32cb having, at 550 nm or less, a light transmittance higher than the light transmittance of the low-transmittance portion 32ca (see Curved Line b in the graph of FIG. 6). It is noted that the low-transmittance portion 32ca is provided in a location not overlapping the imaging region C in the display region D, as illustrated in FIG. 11. It is also noted that the low-transmittance portion 32ca can be formed by not performing ultraviolet irradiation via a photomask between pre-baking and post-baking, and that the high-transmittance portion 32cb can be formed by selectively performing ultraviolet irradiation via a photomask between pre-baking and post-baking to thus make the portion transparent.

The organic EL display device 50ba of the foregoing configuration, which is structured such that the low-transmittance portion 22da of the first flattening film 22d, the low-transmittance portion 25ba of the second flattening film 25b, and the low-transmittance portion 32ca of the edge cover 32c are provided in a location not overlapping the imaging region C, achieves a high light transmittance in the imaging region C, thus enabling favorable imaging.

The organic EL display device 50b according to this embodiment can be manufactured by, in the step of forming the TFT layer of the method for manufacturing the organic EL display device 50a according to the first embodiment, forming sequentially forming a titanium film (about 50 nm thick), an aluminum film (about 400 nm thick), a titanium film (about 50 nm thick) and other components onto the substrate surface with the flattening film 22a (first flattening film 22a) formed thereon, through, for instance, sputtering to thus form a metal stacked film, followed by patterning the metal stacked film to thus form the relay electrode 24a, followed by applying a photosensitive resin film of acrylic (about 2 μm thick) onto the substrate surface with the relay electrode 24a formed thereon, through, but not limited to, slit coating, followed by subjecting this applied film to pre-baking, exposure, development, and post-baking to thus form the second flattening film 25a. It is noted that in forming the second flattening film 25a, no ultraviolet irradiation for making the film transparent is performed between the development and the post-baking.

As described above, the organic EL display device 50b according to this embodiment is structured such that the first flattening film 22a, provided so as to cover the initialization TFT 9a, compensation TFT 9b, write TFT 9c, driving TFT 9d, power supply TFT 9e, emission control TFT 9f, and anode discharge TFT 9g, is entirely a low-transmittance portion having a light transmittance of 80% or less at 450 nm. This structure can prevent light-irradiation-caused deterioration in the properties of the initialization TFT 9a, compensation TFT 9b, write TFT 9c, driving TFT 9d, power supply TFT 9e, emission control TFT 9f, and anode discharge TFT 9g. The first TFTs, such as the anode discharge TFT 9g, including the first semiconductor layer 17a composed of an oxide semiconductor possibly involve deterioration in their properties due to radiation of light of a short wavelength of 500 nm or less; such light-irradiation-caused deterioration in the TFT's properties can be effectively prevented particularly in the first TFTs. This prevents image sticking and other phenomena during image display, thereby achieving high display quality. Further, a camera, a fingerprint sensor, a face authentication sensor, and other things can function even when they are placed on the back side (a side adjacent to the resin substrate layer 10), because a high light transmittance is achieved in a wavelength region that is used with a sensor for wavelength 550 nm or greater.

In addition, the organic EL display device 50b according to this embodiment, which is structured such that the second flattening film 25a, provided on the first flattening film 22a, is, as well, entirely a low-transmittance portion having a light transmittance of 80% or less at 450 nm, can further prevent light-irradiation-caused deterioration in the properties of the initialization TFT 9a, compensation TFT 9b, write TFT 9c, driving TFT 9d, power supply TFT 9e, emission control TFT 9f, and anode discharge TFT 9g.

In addition, the organic EL display device 50b according to this embodiment, which is structured such that the entire edge cover 32a is, as well, a low-transmittance portion having a light transmittance of 80% or less at 450 nm, can further prevent light-irradiation-caused deterioration in the properties of the initialization TFT 9a, compensation TFT 9b, write TFT 9c, driving TFT 9d, power supply TFT 9e, emission control TFT 9f, and anode discharge TFT 9g.

### Other Embodiments

Although the foregoing embodiments have each described, by way of example, an organic EL layer of five-ply stacked structure composed of a hole injection layer, a hole transport layer, a light-emitting layer, an electron transport layer, and an electron injection layer, the organic EL layer may be of, for instance, three-ply stacked structure composed of a hole injection-and-transport layer, a light-emitting layer, and an electron transport-and-injection layer.

Further, although the foregoing embodiments have each described, by way of example, an organic EL display device having a first electrode as an anode, and a second electrode as a cathode, the disclosure is also applicable to an organic EL display device with the stacked structure of its organic EL layer being inverted: a first electrode as a cathode, and a second electrode as an anode.

Further, although the foregoing embodiments have each described an organic EL display device as a display device by way of example, the disclosure is applicable to a display device that includes a plurality of light-emitting elements that are driven by current; for instance, the disclosure is applicable to a display device that includes quantum-dot light-emitting diodes (QLEDs), which are light-emitting elements composed of a quantum-dot-containing layer.

### INDUSTRIAL APPLICABILITY

As described above, the disclosure is useful for flexible display devices.

1. A display device comprising:
a base substrate;
a thin-film transistor layer provided on the base substrate;
a light-emitting element layer provided on the thin-film transistor layer, with a plurality of first electrodes, an edge cover that is common, a plurality of light-emitting functional layers, and a second electrode that is common being stacked sequentially in correspondence with a plurality of subpixels constituting a display region,
the thin-film transistor layer including a first thin-film transistor provided for each of the plurality of subpixels, the first thin-film transistor having a first semiconductor layer composed of an oxide semiconductor; and
a flattening film provided on the first thin-film transistor all over the display region,
wherein in at least a location overlapping the first thin-film transistor, the flattening film has a low-transmittance portion having a light transmittance of 80% or less at 450 nm.

2. The display device according to claim 1, wherein
the first thin-film transistor includes
the first semiconductor layer provided on a first interlayer insulating film, the first semiconductor layer having a first conductor region and a second conductor region defined so as to be spaced from each other, and a first channel region defined between the first conductor region and the second conductor region,
a first gate insulating film provided on the first semiconductor layer,
a first gate electrode provided on the first gate insulating film so as to overlap the first channel region,
a second interlayer insulating film provided so as to cover the first gate electrode, and
a first terminal electrode and a second terminal electrode provided on the second interlayer insulating film so as to be spaced from each other, and electrically connected to the first conductor region and the second conductor region, respectively.

3. The display device according to claim 2, wherein the thin-film transistor layer includes, in addition to the first thin-film transistor, a second thin-film transistor provided for each of the plurality of subpixels, the second thin-film transistor having a second semiconductor layer composed of polysilicon.

4. The display device according to claim 3, wherein
the second thin-film transistor includes
the second semiconductor layer having a third conductor region and a fourth conductor region defined so as to be spaced from each other, and a second channel region defined between the third conductor region and the fourth conductor region,
a second gate insulating film provided on the second semiconductor layer,
a second gate electrode provided on the second gate insulating film so as to overlap the second channel region,
the first interlayer insulating film and the second interlayer insulating film sequentially provided so as to cover the second gate electrode, and
a third terminal electrode and a fourth terminal electrode provided on the second interlayer insulating film so as to be spaced from each other, and electrically connected to the third conductor region and the fourth conductor region, respectively.

5. The display device according to claim 2, wherein the first thin-film transistor includes a third gate electrode provided on the first semiconductor layer adjacent to the base substrate, with the first interlayer insulating film interposed between the third gate electrode and the first semiconductor layer so as to overlap the first semiconductor layer.

6. The display device according to claim 4, wherein the flattening film has the low-transmittance portion in a location overlapping the second gate electrode, the third terminal electrode, and the fourth terminal electrode.

7. The display device according to claim 1, wherein the edge cover has the low-transmittance portion.

8. The display device according to claim 1, wherein the flattening film is composed of an acrylic resin.

9. The display device according to claim 1, wherein
the flattening film includes
a first flattening film provided in a location adjacent to the base substrate, and
a second flattening film provided on the first flattening film, and
in each of the plurality of subpixels, the thin-film transistor layer includes a relay electrode provided between the first flattening film and the second flattening film to relay an electrical connection between the first thin-film transistor and a corresponding one of the plurality of first electrodes.

10. The display device according to claim 9, wherein the first flattening film and the second flattening film have the low-transmittance portion entirely.

11. The display device according to claim 10, wherein
an imaging region is provided within the display region,
in the subpixel in the imaging region, the relay electrode is extended, so that the first thin-film transistor corresponding to the subpixel is provided in the subpixel around the imaging region, and
the first flattening film, the second flattening film, and the edge cover have the low-transmittance portion in a location not overlapping the imaging region.

12. The display device according to claim 1, comprising a sealing film provided so as to cover the light-emitting element layer.

13. The display device according to claim 1, wherein each of the plurality of light-emitting functional layers is an organic electroluminescence layer.
